(19) United States
(12) Patent Application Publication
(10) Pub. No.: US 2007/0272912 A1
(43) Pub. Date: Nov. 29, 2007

(54) Conductive paste and method of manufacturing electronic component using the same

(75) Inventors: Hitoshi Onishi, Niigata-ken (JP); Satoshi Yamada, Niigata-ken (JP); Akira Sekiguchi, Niigata-ken (JP)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: Alps Electric Co., Ltd., Ota-ku (JP)

(21) Appl. No.: 11/798,398

(22) Filed: May 14, 2007

(30) Foreign Application Priority Data
May 15, 2006 (JP) 2006-135325

(51) Int. Cl. H01L 47/00; H01L 39/22

(52) U.S. Cl. 257/4; 216/13; 257/44; 257/32

(57) ABSTRACT

Exemplary embodiments provided a conductive paste including an organic gold compound and a glass component in a solvent. When electrodes are formed on both surfaces of piezoelectric members using the conductive paste according to the invention, it is possible to improve the close adhesion property between the electrodes and the piezoelectric members eliminate ion migration, and lower electric resistances of the electrodes.

This application claims the benefit of Japanese Patent Application No. 2006-135325, filed on May 15, 2006, the content of which is incorporated herein by reference.

### BACKGROUND OF THE INVENTION

1. Field of the Invention

The present invention relates to a conductive paste used in, for example, an electrode of a bimorph-typeora unimorph piezoelectric element, and more particularly, to a conductive paste capable of realizing both excellent adhesion property and low electric resistance between the electrode and a substrate (a piezoelectric member) and preventing generation of cracks in the substrate and a method of manufacturing an electronic component using the conductive paste.

2. Description of the Related Art

A conductive film containing silver is used as an electrode material of a piezoelectric element. The piezoelectric element may be used as a diaphragm of a coolant circulation pump.

However, ion migration of the silver is caused in the electrode containing the silver. Particularly, the ion migration is prominent in such a condition where the electrode is in contact with fluid directly or via a resin film. In the case of the conductive film containing palladium in addition to the silver, the ion migration is suppressed to some degree but not practically usable.

In the related art, such as JP-A-11-346013, JP-A-2002-246258, JP-A-2002-293624, JP-A-2005-51840, or JP-A-2005-39178, there is disclosed an electrode formed of metals such as gold or platinum, capable of preventing the ion migration appropriately.

However, the electrode formed of metals such as gold or platinum showed very poor adhesion property between the electrode and a piezoelectric member.

The piezoelectric member is formed of PZT (that is a solid fluid of lead titanate (PbTiO₃) and lead zirconate (PbZrO₃)), and contains a large amount of oxygen.

However, since the gold or platinum is a metal that is hardly oxidized, that is, hardly combines with oxygen, the bonding force at an interface between the electrode and the piezoelectric member becomes weak even when the electrode of gold is formed on the piezoelectric member. Therefore, the electrode is easily peeled away from the piezoelectric member.

In the above-mentioned related art, there is disclosed an electrode formed of a metal resinate such as a gold resinate. However, even in the case of the electrode formed of the metal resinate, the adhesion property between the electrode and the piezoelectric member was not improved appropriately. The poor adhesion property will be proven by the experiment described later.

### SUMMARY OF THE INVENTION

The embodiments described herein solve the problems in the above-mentioned related art. Particularly, an object of the invention is to provide a conductive paste capable of realizing both excellent adhesion property and low electric resistance between the electrode and a substrate (a piezoelectric member) and preventing generation of cracks in the substrate and a method of manufacturing an electronic component using the conductive paste.

According to a first embodiment, there is provided a conductive paste consisting essentially of an organic gold compound and a glass component.

When a conductive film (the electrode) is formed on the substrate using the conductive paste according to the invention, it is possible to remarkably improve the adhesion property between the conductive film and the substrate. In addition, since silver is not contained in the conductive film, the ion migration is not caused. Moreover, it is possible to lower electric resistance of the conductive film and prevent generation of cracks in the substrate (for example, the piezoelectric member) even when used in vibrating piezoelectric element.

In a second embodiment, the content of the glass component with respect to the total amount of gold may be in the range of approximately 4 to 35 mass %. According to the test results to be described later, both the excellent adhesion property and the low resistance between the electrode and the substrate are realized.

In a third embodiment, the content of the glass component may be approximately 8% mass % or more since the adhesion property between the electrode and the substrate can be improved remarkably.

In a fourth embodiment, the content of the glass component may be approximately 32 mass % or less since the low resistance can be realized.

In a fifth embodiment, the average particle diameter of the glass component may be approximately 1 μm or less. As described above, since the glass component is formed of fine powder of average particle diameter of 1 μm or less, the adhesion property between the electrode and the substrate can be improved more effectively.

According to a sixth embodiment, there is provided a method of manufacturing an electronic component having a substrate and an electrode formed on the surface of the substrate, wherein an electrode pattern is formed on the surface of the substrate using the conductive paste according to the above conductive paste is then baked to form the electrode.

In this embodiment, it is possible to improve the adhesion property between the electrode and the substrate remarkably. In addition, since the silver is not contained in the electrode, it is possible to prevent the ion migration and lower the electric resistance of the electrode.

The electronic component may include a piezoelectric element having a metal plate, a piezoelectric member as the substrate formed on at least one surface of the metal plate, and an electrode formed on both surfaces of the piezoelectric member. In addition to the effects, it is possible to prevent the generation of the cracks in the vibrating piezoelectric element appropriately.

### BRIEF DESCRIPTION OF THE DRAWINGS

FIG. 1 is a perspective view of a bimorph-type piezoelectric element.

FIG. 2 is a partially sectional view of the bimorph-type piezoelectric element taken along the 2-2 line shown in FIG. 1 and viewed in a direction of the arrows.

FIGS. 3A and 3B are diagrams for explaining the principle of a diaphragm pump using the bimorph-type piezoelectric element.

FIG. 4 is a picture of a surface of an electrode formed of a conductive paste according to Example 1 (a gold resinate and 8 mass % of glass), photographed by an electron microscope.

FIG. 5 is a picture of a surface of an electrode formed of a conductive paste according to Example 4 (a gold resinate and 8 mass % of fine glass powder), photographed by the electron microscope.

FIG. 6 is a photograph of a surface of an electrode formed of a conductive paste according to Example 7 (a gold resinate and 32 mass % of fine glass powder), photographed by the electron microscope.

### DESCRIPTION OF THE PREFERRED EMBODIMENT

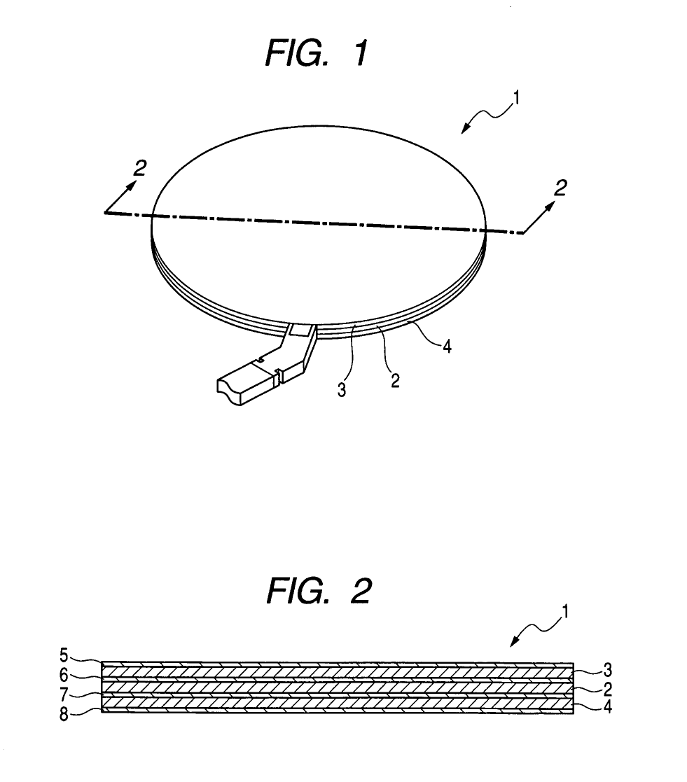

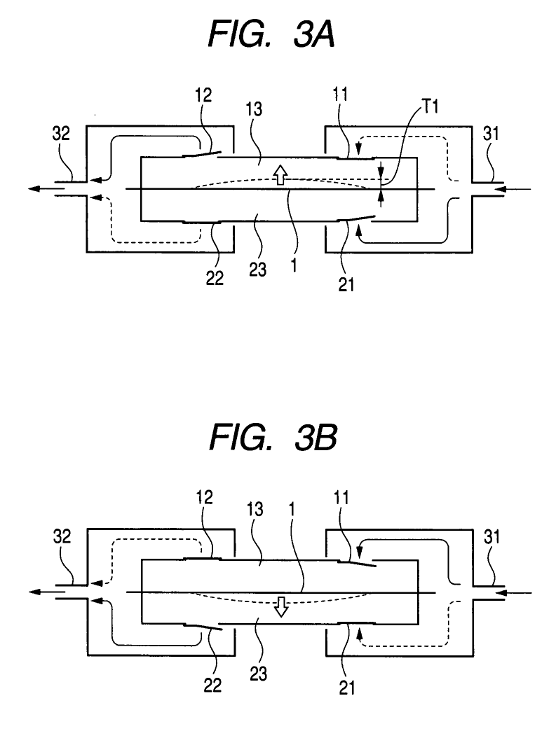

FIG. 1 is a perspective view of a bimorph-type piezoelectric element, FIG. 2 is a partially sectional view of the bimorph-type piezoelectric element taken along the 2-2 line shown in FIG. 1 and viewed in a direction of the arrows. FIGS. 3A and 3B are diagrams for explaining a principle of a diaphragm pump using the bimorph-type piezoelectric element.

A bimorph-type piezoelectric element 1 shown in FIGS. 1 and 2 is configured to include a circular metal plate (or shim) 2 and circular piezoelectric members 3 and 4 provided on both surfaces of the metal plate 2. Insulating cover films (not shown) may be provided on outer surfaces of the piezoelectric members 3 and 4.

The metal plate 2 is formed of a NiFe alloy such as 42 Alloy, Cu, an alloy containing the Cu or the like. The thickness of the metal plate 2 may be about 300 μm.

The piezoelectric members 3 and 4 are formed of PZT [a solid fluid of lead titanate (PbTiO₃) and lead zirconate (PbZrO₃); hereinafter referred to as Pb(Zr_{1/2}Ti_{1/2})O₃], PZN (Pb(Zn_{1/3}Nb_{2/3})O₃), PNN (Pb(Ni_{1/3}Nb_{2/3})O₃), and combinations of the two of PZT, PZN and PNN. As one example, the piezoelectric members 3 and 4 are formed to be expressed by [Pb(Zr_{1/2}Ti_{1/2})O₃]_{0.6}+[Pb(Zn_{1/3}Nb_{2/3})O₃]_{0.16}+[Pb(Ni_{1/3}Nb_{2/3})O₃]_{0.24}. The ratio of elements may be changed depending on the usage.

The centerline average roughness Ra of the surfaces of the piezoelectric members 3 and 4 is in the range of 0.1 to 0.2 μm. The thicknesses of the piezoelectric members 3 and 4 may be about 300 μm.

The piezoelectric members 3 and 4 are polarized in the same direction as the thickness direction thereof.

As shown in FIG. 2, electrodes 5, 6, 7 and 8 are formed on the surfaces of the respective piezoelectric members 3 and 4. The inner electrodes 6 and 7 formed on the piezoelectric members 3 and 4 adhere to the metal plate 2 via adhesive layers (not shown).

When a common electrode is disposed on the metal plate 2, terminals are disposed on the outer electrodes 5 and 8 of the respective piezoelectric members 3 and 4, and a voltage is applied to the piezoelectric members 3 and 4, the expansion and contraction directions in the film surface are opposite to each other in the piezoelectric members 3 and 4. The piezoelectric element 1 can be deformed to be expanded upward as shown in FIG. 3A, or can be deformed to be depressed downward as shown in FIG. 3B. An alternating electric current is applied to the piezoelectric element 1 so that the deformations shown in FIGS. 3A and 3B are repeated. As a result, the piezoelectric element 1 vibrates.

As shown in FIGS. 3A and 3B, an upper pump chamber 13 is disposed over the piezoelectric element 1, and a lower pump chamber 23 is disposed under the piezoelectric element 1. A suction-side check valve 11 is disposed between a suction port 31 and the upper pump chamber 13, and a suction-side check valve 21 is disposed between the suction port 31 and the lower pump chamber 23. The suction-side check valves 11 and 21 allow a fluid to move from the suction port 31 to the pump chambers 13 and 23, but do not allow a fluid to move from the pump chambers 13 and 23 to the suction port 31. In addition, a discharge-side check valve 12 is disposed between a discharge port 32 and the upper pump chamber 13, and a discharge-side check valve 22 is disposed between the discharge port 32 and the lower pump chamber 23. The discharge-side check valves 12 and 22 allow a fluid to move from the pump chambers 13 and 23 to the discharge port 32, but do not allow a fluid to move from the discharge port 32 to the pump chambers 13 and 23.

As shown in FIG. 3A, since the piezoelectric element (the diaphragm) 1 is deformed so as to be expanded upward, the volume of the upper pump chamber 13 is reduced and the volume of the lower pump chamber 23 is increased. At this time, the suction-side check valve 21 is opened so that the fluid flows from the suction port 31 to the lower pump chamber 23, and the discharge-side check valve 12 is opened so that the fluid in the upper pump chamber 13 flows to the discharge port 32.

As shown in FIG. 3B, since the piezoelectric element (the diaphragm) 1 is deformed so as to be depressed downward, the volume of the lower pump chamber 23 is reduced and the volume of the upper pump chamber 13 is increased. At this time, the suction-side check valve 11 is opened so that the fluid flows from the suction port 31 to the upper pump chamber 13, and the discharge-side check valve 22 is opened so that the fluid in the lower pump chamber 23 flows to the discharge port 32. By repeating the operations, it is possible to obtain the pumping action. The pumping action may be applied to a coolant circulation pump of a notebook computer.

In this embodiment, the electrodes 5, 6, 7 and 8 are formed by the following method. That is, a conductive paste in which an organic gold compound and glass component is contained in a solvent is applied to the surfaces of the respective piezoelectric members 3 and 4 by screen-printing, degreased and then baked to form the electrodes 5, 6, 7 and 8.

The organic gold compound is a fatty acid gold represented by, for example, CₙHₘCOO—Au (n is 0 or more, m is 1 or more). The number of carbon is not particularly limited. The fatty acid gold may be any one of a lower fatty acid and a higher fatty acid. Specifically, the fatty acid gold is formed of gold formate, gold acetate, gold caprylate or the like. The fatty acid gold may be normal chain fatty acid gold, a branched fatty acid gold and cyclic fatty acid gold. However, the organic gold compound is not limited to the fatty acid golds.

The organic gold compound is prepared using resinate that is dispersed and dissolved in the solvent in a non-uniform manner. Hereinafter, the “organic gold compound” is referred to as a “gold resinate,” unless otherwise noted.

The material of glass component is not particularly limited. The known compositions including silica glass, soda-lime glass, borosilicate glass, lead glass, fluoride glass or the like can be used as the glass component.

As the solvent, aliphatic alcohol, alcoholic ester, carbitol or the like may be used, but the material of the solvent is not particularly limited to this.

The temperature at the time of baking corresponds to the temperature at which the gold resinate and the glass component are dissolved. In this embodiment, it is possible to set the baking temperature in the range of about 600 to about 700° C. When the temperature is raised to the range of about 300 to about 400° C., the organics of the gold resinate are thermally decomposed and evaporated, thus the gold is dispersed at an atomic level as if the gold is dissolved. The gold is not dissolved when the temperature is not raised to 1000° C. or more. However, since the gold resinate is used, it is possible to realize the same state as the dissolved gold at a temperature lower than a normal dissolving temperature. The gold atoms are collected so that the surfaces of the piezoelectric bodies are covered by gold layers.

Next, when the baking temperature is raised to about 600° C. or more, the glass component is dissolved. In accordance with the composition of the glass component, the dissolving temperature is different. When the glass component is dissolved, the glass component is intruded into gaps between the gold layers and the piezoelectric members and finally into areas adjacent to the surfaces of the piezoelectric members. Accordingly, the adhesion property between the metal and the piezoelectric members is increased.

As described above, since the organic compound is thermally decomposed and evaporated by the baking process and the glass component is dissolved, the electrode after the baking has a film thickness about several tens to several hundreds times smaller than that of the conductive paste at the time of initial printing. Specifically, when the film thickness of the conductive paste at the time of printing is about 20 μm, the film thickness of the electrode after the baking is decreased in the range about 0.1 to about 0.5 μm.

In this embodiment the amount of glass component to be contained in the conductive paste may be set in the range of approximately 4 to 35 mass % with respect to the total amount of gold. When the glass component is set to less than 4 mass %, the adhesion property between the electrode and the piezoelectric member may become weak. As a result, the electrode is may peel away from the piezoelectric body easily. When the glass component is set to more than 35 mass % , the resistance value of the electrode may increase.

The contained amount of glass component may be set approximately to 8 mass % or more since the adhesion property can be improved more effectively.

In addition, the contained amount of glass component may also be set to approximately 32 mass % or less since the resistance value can be reduced more effectively.

The average particle diameter of glass component in the conductive paste may be approximately 1 μm or less. The glass component of which the average particle diameter is 1 μm or less is referred to as fine glass powder in order to differentiate from the glass component of which the average particle diameter is more than 1 μm. When the average particle diameter of the glass component is too large, however the glass component contained in the conductive paste with the above-described content range, the glass component cannot be scattered at a short distance from one another at the time of printing the conductive paste on the piezoelectric member. Accordingly, it is desirable that the glass component become finer as described above. When the glass component having large average particle diameter are scattered at a long distance from one another on the piezoelectric member, the dissolved glass cannot be spread widely. As a result, places in which the adhesion property between the electrode and the piezoelectric member is weak are formed easily. Therefore, by setting the contained amount of glass component so as to be in the above-described range and setting the average particle diameter of glass component so as to be 1 μm or less, the glass component can be scattered from one another at a short distance and dispersed uniformly on the piezoelectric member at the time of printing the conductive paste on the piezoelectric member, thus the dissolved glass is spread widely at the time of baking. Accordingly, it is possible to improve the adhesion property between the electrode and the piezoelectric member more effectively.

In this embodiment, the average particle diameter of glass component contained in the conductive paste may be set in the range of approximately 0.3 to 0.5 μm.

As described above, when the conductive paste having the gold resinate and the glass component in the solvent is printed on the surfaces of the respective piezoelectric members 3 and 4 and then baked, the organics of the gold resinate are thermally decomposed and evaporated. Accordingly, the electrodes 5, 6, 7 and 8 after the baking are formed of the gold and glass component. In addition, in this embodiment, it is possible to reduce the film thicknesses of the electrodes 5, 6, 7 and 8 as described above.

In this embodiment, it is possible to maintain the excellent adhesion property between the electrodes 5, 6, 7 and 8 and the piezoelectric members 3 and 4, and the gold is used as the main component in the electrodes. Accordingly, the electrodes 5, 6, 7 and 8 can be formed to have low resistances, and ion migration does not occur even under the bad conditions of high-temperature, humidity and the like.

It can be seen that it is possible to prevent the cracks from forming in the piezoelectric members 3 and 4 of the piezoelectric element 1 properly even when vibrating the piezoelectric element 1 as shown in FIGS. 3A and 3B from the tests to be described later.

In addition, even when the electrodes are formed of the conductive paste including the glass component of approximately 32% by mass or less with respect to the total amount of gold, it can be seen from the test results to be described later that capacitances and amplitudes (the maximum displacement) (T1×2 shown in FIG. 3A) of the piezoelectric members 3 and 4 are almost the same as those in the case of electrodes formed of a conductive paste not including the glass component. That is, it is possible to maintain the high performance of the piezoelectric element 1.

The conductive paste according to the embodiment may be used as an electrode pattern of a flexible printed circuit board and the like in addition to a use as the electrodes of the piezoelectric element 1. In this embodiment, the electrode pattern has excellent bendability (that is, cracks are not formed in the electrode pattern). However, it is necessary to form the printed circuit board of a material that can resist the baking temperature.

In addition, the piezoelectric element 1 according to the embodiment is the bimorph-type piezoelectric element, but may be a unimorph-type piezoelectric element, a laminated type piezoelectric element and the like.

### EXAMPLES

Conductive pastes of the composition shown in the following Table 1 were applied to an entire surface of a circular substrate expressed by [Pb(Zr_{1/2}Ti_{1/2})O₃]_{0.6}+[Pb(Zn_{1/3}Nb_{2/3})O₃]_{0.16}+[Pb(Ni_{1/3}Nb_{2/3})O₃]_{0.24} (about 28 mm in diameter) (a piezoelectric member) by screen-printing and then baked at 650° C. for 30 minutes so as to form electrodes. A centerline average roughness Ra of the surface of the substrate was in the range of 0.1 to 0.2 μm in all samples.

A tape having a predetermined adhesion property was attached to the electrode, and a peel test was carried out for measuring whether the electrode was peeled away from the substrate at the time of removing the tape.

TABLE 1

| | | Tape adhesion property | | | | | |
|---|---|---|---|---|---|---|---|
| | Conductive | 157 gf/cm | | 288 gf/cm | | 438 gf/cm | |
| Sample | paste | Initial | | Initial | | Initial | After |
| No. | composition | stage | After test | stage | After test | stage | test |
| Example 1 | Gold resinate | 0/10 | 0/10 | — | 6/10 | — | 0/10 |
| Example 2 | Gold resinate | 0/10 | 0/10 | — | 4/10 | — | 0/10 |
| | and 4% of fine | | | | | | |
| | glass powder | | | | | | |
| Example 3 | Gold resinate | 0/10 | 0/10 | — | 2/10 | — | 0/10 |
| | and 5% of fine | | | | | | |
| | glass powder | | | | | | |
| Example 4 | Gold resinate | 0/10 | 0/10 | — | 0/10 | — | 0/10 |
| | and 8% of fine | | | | | | |
| | glass powder | | | | | | |
| Example 5 | Gold resinate | 0/10 | 0/10 | — | 0/10 | — | 0/10 |
| | and 16% of fine | | | | | | |
| | glass powder | | | | | | |
| Example 6 | Gold resinate | 0/10 | 0/10 | — | 0/10 | — | 0/10 |
| | and 24% of fine | | | | | | |
| | glass powder | | | | | | |
| Example 7 | Gold resinate | 0/10 | 0/10 | — | 0/10 | — | 0/10 |
| | and 32% of fine | | | | | | |
| | glass powder | | | | | | |
| Comparative | Gold resinate | 5/10 | 8/10 | — | 10/10 | — | 10/10 |
| Example | (not containing | | | | | | |
| | glass) | | | | | | |

In the samples of Examples 1 to 7, commercially available gold resinates and glass components were contained in the conductive pastes. The contained amount of glass component shown in the Table 1 is mass % with respect to the total amount of gold. “Fine glass powder” refers to glass powder having an average particle diameter of 1 μm or less, and the fine glass powder used in the tests had an average particle diameter in the range of 0.3 to 0.5 μm. In the Example 1, the “fine glass powder” was not used, but the glass component having an average particle diameter in the range of 3 to 5 μm was used. In order to obtain the average particle diameter of glass powder, major axes of 30 samples of the glass powder in the conductive paste were measured by a scanning electron microscope and the average value was calculated and specified. The glass component was not contained in the conductive paste of the Comparative Example. The thicknesses of electrodes of the samples were in the range of 0.1 to 0.5 μm.

The peel test with the tape having the adhesion property of 157 gf/cm was performed to the electrodes of the respective samples. In the Table 1, “initial stage” is used to describe the peel test performed right after the electrodes were formed, and “after test” is used to describe the peel test carried out after the electrodes were formed and left under the condition of a temperature of 85° C. and a humidity of 90% for 72 hours. The test was carried out for ten times (denominators in the Table 1) in each of the Examples and Comparative Example so that the number of samples in which the electrode was peeled away from the substrate was measured (numerators in the Table 1).

Similarly, the peel test with the tapes having the adhesive properties of 288 gf/cm and 438 gf/cm was carried out in the “after test.”

As shown in the Table 1, the bad result was obtained in the Comparative Example. Particularly, when using the tape having the adhesion property of 157 gf/cm, the electrodes of the samples of the Examples were not peeled away from the substrate at all, but the electrode of the sample of the Comparative Example was peeled away from the substrate. Accordingly, it can be seen that the adhesion property between the electrode and the substrate was poor in the Comparative Example.

As shown in the Table 1, in the Examples 1 to 7, the results obtained by performing the peel test were excellent. However, in the Example 1 in which the glass component was not the fine glass powder and in the Examples 2 and 3 in which the contained amounts of glass component were small, several electrodes of the samples were peeled away from the substrate when using the tape having the adhesion property of 288 gf/cm.

From the test results shown in the Table 1, it can be seen that it is preferable that the glass component is the fine glass powder and the contained amount of glass component is 4 mass % or more, more preferably 8 mass % or more.

As shown in the Table 1, it can be seen that the excellent adhesion property can be obtained by increasing the contained amount of glass component. However, from the following test results, it can be seen that the resistance value of the electrode was increased when too large amount of glass component was contained in the electrode.

Both ends of the respective electrodes of the Example 1 (“8% of glass” shown in the following Table 2), the Example 4 (“8% of fine powder” shown in the Table 2) and the Example 7 (“32% of fine powder” shown in the Table 2) used in the tests of the Table 1 were connected to a terminal, and the electric resistances of the electrodes were measured.

As in the case of forming the samples of the Table 1, a conductive paste (“35% of fine powder” shown in the Table 2) having the gold resinate and the fine glass powder (the average particle diameter of the powder was in the range of 0.3 to 0.5 μm) of 35 mass % with respect to the total amount of gold and a conductive paste (“38% of fine powder” shown in the Table 2) having the gold resinate and the fine glass powder (the average particle diameter of the powder was in the range of 0.3 to 0.5 μm) of 38 mass % with respect to the total amount of gold were applied to an entire surface of a circular substrate (about 28 mm in diameter) (the piezoelectric member) by screen-printing and then baked at 650° C. for 30 minutes so as to form electrodes. In addition, both ends of the respective electrodes were connected to the terminal, and the electric resistances of the electrodes were measured.

TABLE 2

| | | 8% of | 32% of | 35% of | 38% of |
|---|---|---|---|---|---|
| Sample | 8% of | fine | fine | fine | fine |
| No. | glass | powder | powder | powder | powder |
| 1 | 2.4 | 1.4 | 2.6 | 5.1 | 15.4 |
| 2 | 2.5 | 1.3 | 2.6 | 5.5 | 12.3 |
| 3 | 2.5 | 1.4 | 2.7 | 4.8 | 17.8 |
| 4 | 2.4 | 1.4 | 2.6 | 5.2 | 18.2 |
| 5 | 2.5 | 1.4 | 2.7 | 5.3 | 14.7 |

As shown in the Table 2, the samples having the “38% of fine powder” were larger in resistance value than other samples by one digit. From the test results of the Table 2, the upper limit of the contained amount of glass component was set to 35 mass % , and it can be seen that it is preferable that the upper limit of the contained amount of glass component is 32 mass %.

Next, the surfaces of the electrodes of the respective Example 1 (gold resinate and 8% of glass), the Example 4 (gold resinate and 8% of fine glass powder) and the Example 7 (gold resinate and 32% of fine glass powder) shown in the Table 1 were taken by an electron microscope.

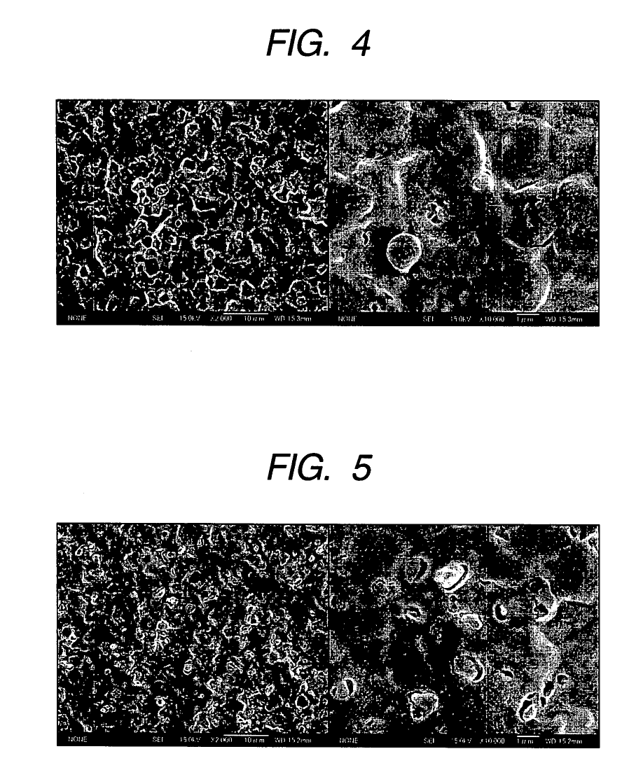

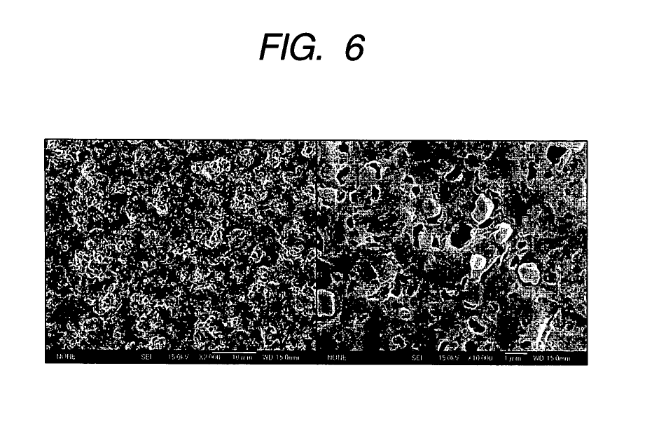

FIG 4 is a picture of the Example 1, FIG. 5 is a picture of the Example 4, and the FIG. 6 is a picture of the Example 7. The right pictures of the figures are pictures showing enlarged views of portions of the left pictures of the figures.

As shown in FIGS. 4 to 6, it can be seen that holes were formed on the surfaces of the respective electrodes. It seems that the holes were formed due to the glass component dissolved at the time of baking. As shown in FIG. 6, it can be seen that the number of holes formed in the Example 7 in which the contained amount of glass component was large was larger than those of formed in the Examples 1 and 4 shown in FIGS. 4 and 5, respectively. It seems that portions marked “particle” in the figures are glass component or portions formed by the gold covering the holes partially.

The existence of holes serves as an indicator showing that the glass component is contained in the conductive paste and thus eliminates a need to analyze the composition of the electrode. It is desirable that a moderate amount of holes is formed. A large amount of holes means that the amount of contained glass component is large and the gold is likely to be overwhelmed by the glass, thereby increasing the resistance value of the electrode, as described in the Table 2.

Next, the bimorph-type piezoelectric element shown in the FIGS. 1 and 2 was formed by using the conductive pastes shown in the Examples 1 and 4 of the Table 1, and the actual formation of cracks in the piezoelectric member at the time of vibrating the piezoelectric element was measured. Preparing 31 samples for each of the Examples 1 and 4 and analyzing the formation of cracks, the samples of the Example 4 had no cracks, but 4 of the 31 samples of the Example 1 had the cracks.

The glass component contained in the conductive paste of the Example 1 was not the fine glass powder but the component having a relatively large average particle diameter in the range of 3 to 5 μm, and the poorest adhesion property was shown in the Example 1 as shown in the Table 1. On the other hand, the excellent adhesion property was shown in the Example 4 as shown in the Table 1. The formation of crack in the piezoelectric member relates to the close adhesion property.

That is, in the 4 samples of the Example 1 in which the cracks were formed in the piezoelectric member, a part of electrode was peeled away from the piezoelectric member. The piezoelectric member from which the electrode is peeled away is not displaced, and the piezoelectric member to which the electrode adheres may be displaced. Such a localized piezoelectric effect is expected to form the cracks in the piezoelectric member easily. In the samples of the Example 4, the adhesion property between the electrode and the piezoelectric member was excellent so that the cracks were not formed in the piezoelectric member.

Next, electrodes of the bimorph-type piezoelectric element shown in the FIGS. 1 and 2 were formed by using the conductive pastes shown in the Comparative Example 1 and the Examples 5, 6, and 7 of the Table 1, and the amplitude (the maximum displacement) (T1×2 shown in FIG. 3A) of the piezoelectric element and capacitance of the piezoelectric member at the time of vibrating the piezoelectric element were measured.

When the electrode formed by using the conductive paste of the Comparative Example was used, the maximum amplitude was 86 μm and the capacitance was 167 μF.

When the electrode formed by using the conductive paste of the Example 5 (gold resinate and 16% of the fine glass powder) was used, the maximum amplitude was 86 μm and the capacitance was 167 μF, when the electrode formed by using the conductive paste of the Example 6 (gold resinate and 24% of the fine glass powder) was used, the maximum amplitude was 87 μm and the capacitance was 170 μF, and when the electrode formed by using the conductive paste of the Example 7 (gold resinate and 32% of the fine glass powder) was used, the maximum amplitude was 85 μm and the capacitance was 167 μF. Particularly large differences in the maximum amplitude and the capacitance were not generated.

This is because the electrodes formed of the conductive pastes are properly functioning as a low-resistance electrode over a large area. The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A conductive paste consisting essentially of an organic gold compound and a glass component.

2. The conductive paste according to claim 1, wherein the content of the glass component with respect to the total amount of gold is in the range of approximately 4 to 35 mass %.

3. The conductive paste according to claim 2, wherein the content of the glass component is approximately 8 mass % or more.

4. The conductive paste according to claim 3, wherein the content of the glass component is approximately 32 mass % or less.

5. The conductive paste according to claim 1, wherein the average particle diameter of the glass component is approximately 1 μm or less.

6. A method of manufacturing an electronic component having a substrate and an electrode formed on the surface of the substrate, wherein an electrode pattern is formed on the surface of the substrate using the conductive paste according to claim 1 and the conductive paste is then baked to form the electrode.

7. The method according to claim 6, wherein the electronic component is a piezoelectric element having a metal plate, a piezoelectric member as the substrate formed on at least one surface of the metal plate, and the electrode formed on both surfaces of the piezoelectric member.

8. A piezoelectric element, comprising:
a substrate having a surface, and
an electrode formed on the surface of the substrate,
wherein the surface of the substrate comprises a conductive paste consisting essentially of an organic gold compound and a glass component.

9. The piezoelectric element according to claim 8, further comprising:
a metal plate having at least one surface; and
a piezoelectric member as the substrate formed on the at least one surface of the metal plate, the piezoelectric member having first and second surfaces,
wherein the electrode is formed on the first and second surfaces of the piezoelectric member.

10. The piezoelectric member according to claim 8, wherein the content of the glass component with respect to the total amount of gold is in the range of approximately 4 to 35 mass %.

11. The piezoelectric member according to claim 10, wherein the content of the glass component is approximately 8 mass % or more.

12. The piezoelectric member according to claim 11, wherein the content of the glass component is approximately 32 mass % or less.

13. The piezoelectric member according to claim 8, wherein the average particle diameter of the glass component is approximately 1 μm or less.
